(19) United States
(12) Patent Application Publication
(10) Pub. No.: US 2025/0123429 A1
(43) Pub. Date: Apr. 17, 2025

(54) ELECTRONIC DEVICE

(71) Applicants: InnoLux Corporation, Miao-Li County (TW); CARUX TECHNOLOGY PTE. LTD., SINGAPORE (SG)

(72) Inventors: Yen-Chi CHANG, Tainan (Tainan Science Park) (TW); Min-Chien SUNG, Tainan (Tainan Science Park) (TW); Po-Tsun KUO, Tainan (Tainan Science Park) (TW); Yu-Kai WANG, Tainan (Tainan Science Park) (TW); Wei-Lun HSIAO, Miao-Li County (TW); Cheng-Yang TSAI, Tainan (Tainan Science Park) (TW); Yu-Ting CHEN, Tainan (Tainan Science Park) (TW)

(21) Appl. No.: 18/828,224

(22) Filed: Sep. 9, 2024

(30) Foreign Application Priority Data
Oct. 12, 2023 (CN) 202311321856.4

(51) Int. Cl. G02B 5/00

(52) U.S. Cl. CPC G02B 5/003

(57) ABSTRACT

An electronic device is provided. The electronic device includes a panel, a protective substrate, and a first light-shielding structure. The panel has an active area and a peripheral area. The peripheral area is adjacent to the active area. The protective substrate is disposed opposite to the panel. The first light-shielding structure is disposed on a surface of the protective substrate and corresponds to the peripheral area. A portion of the first light-shielding structure that overlaps the peripheral area has at least one opening.

### CROSS REFERENCE TO RELATED APPLICATIONS

This application claims the benefit of China Application No. 202311321856.4, filed Oct. 12, 2023, the entirety of which is incorporated by reference herein.

### BACKGROUND

### Technical Field

The present disclosure is related to an electronic device, and in particular it is related to an electronic device having a light-shielding structure.

### Description of the Related Art

Electronic devices that are equipped with panels have become indispensable necessities in modern society. Consumers have high expectations regarding the viewing quality and functionality of these electronic products.

However, these electronic products still do not meet expectations in all respects. For example, the obvious difference in transmittance between the light-shielding structure of the protective substrate and the active area can easily create the appearance of a visual boundary. Therefore, developing a structure that can improve the viewing quality or performance of electronic devices is still one of the current research topics in the industry.

### SUMMARY

In accordance with some embodiments of the present disclosure, an electronic device is provided. The electronic device includes a panel, a protective substrate, and a first light-shielding structure. The panel has an active area and a peripheral area. The peripheral area is adjacent to the active area. The protective substrate is disposed opposite to the panel. The first light-shielding structure is disposed on a surface of the protective substrate and corresponds to the peripheral area. A portion of the first light-shielding structure that overlaps the peripheral area has at least one opening.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a top-view diagram of an electronic device in accordance with some embodiments of the present disclosure;

FIG. 2 is a partial cross-sectional diagram of an electronic device in accordance with some embodiments of the present disclosure;

FIG. 3 is a partial top-view diagram of a first light-shielding structure of an electronic device in accordance with some embodiments of the present disclosure;

FIG. 4 is a partial top-view diagram of a first light-shielding structure of an electronic device in accordance with some embodiments of the present disclosure;

FIG. 5 is a partial top-view diagram of a first light-shielding structure of an electronic device in accordance with some embodiments of the present disclosure;

FIG. 6 is a partial cross-sectional diagram of an electronic device in accordance with some embodiments of the present disclosure;

FIG. 7A is a partial top-view diagram of a third light-shielding structure of an electronic device in accordance with some embodiments of the present disclosure;

FIG. 7B is a partial top-view diagram of a third light-shielding structure of an electronic device in accordance with some embodiments of the present disclosure;

FIG. 8 is a partial cross-sectional diagram of an electronic device in accordance with some embodiments of the present disclosure;

FIG. 9 is a partial cross-sectional diagram of an electronic device in accordance with some embodiments of the present disclosure;

FIGS. 10A to 10C are partial cross-sectional diagrams of some elements of an electronic device in accordance with some embodiments of the present disclosure;

FIG. 11 is a partial top-view diagram of a first light-shielding structure of an electronic device in accordance with some embodiments of the present disclosure.

### DETAILED DESCRIPTION

Reference will now be made in detail to the exemplary embodiments of the present disclosure, examples of which are illustrated in the accompanying drawings. Whenever possible, the same reference numerals are used in the drawings and descriptions to refer to the same or similar parts.

The present disclosure can be understood by referring to the following detailed description and combined with the accompanying drawings. It should be noted that in order to make the readers easy to understand and the drawings to be concise, many of the drawings in the present disclosure only depict part of the electronic device, and certain elements in the drawings are not drawn to actual scale. In addition, the number and dimension of each element in the drawings are only for illustration and are not intended to limit the scope of the present disclosure.

Throughout the present disclosure and the appended claims, certain terms are used to refer to specific elements. Those skilled in the art should understand that electronic device manufacturers may refer to the same element with different names. The present disclosure does not intend to distinguish between elements that have the same function but different names. In the specification and claims, the terms “comprising”, “including”, “having” and the like are open-ended phrases, so they should be interpreted as “including but is not limited to . . . ”. Therefore, when the terms “comprising”, “including” and/or “having” are used in the description of the present disclosure, they specify the corresponding features, regions, steps, operations and/or components, but do not exclude the existence of one or more corresponding features, regions, steps, operations and/or components.

The directional terms mentioned herein, such as “above”, “under”, “front”, “rear”, “left”, “right”, etc., are only for reference to the directions of the accompanying drawings. Accordingly, the directional terms used are illustrative and not intended to limit the present disclosure. In the drawings, each figure illustrates the general features of methods, structures, and/or materials used in particular embodiments. However, these drawings should not be interpreted as defining or limiting the scope or feature encompassed by these embodiments. For example, the relative dimensions, thicknesses, and positions of various layers, regions, and/or structures may be reduced or exaggerated for clarity.

According to the present disclosure, one structure (or layer, component, or substrate) described is located on/above another structure (or layer, component, or substrate), which means that the two structures are adjacent and directly connected, or the two structures are adjacent but not directly connected. The description “not directly connected” means that there is at least one intermediary structure (or intermediary layer, intermediary component, intermediary substrate, intermediary spacer) between two structures, the lower surface of one structure is adjacent to or directly connected to the upper surface of the intermediary structure, and the upper surface of another structure is adjacent to or directly connected to the lower surface of the intermediate structure. The intermediary structure can be composed of a single-layer or multi-layer physical structure or a non-physical structure, and the present disclosure is not limited thereto. In the present disclosure, when a structure is disposed “on” another structure, it means that the structure is “directly” on another structure, or that the structure is “indirectly” on another structure, that is, at least one structure is also sandwiched between the structure and another structure.

The terms “equal to” or “the same”, “substantially” or “approximately” are generally interpreted as being within 20% of a given value or range, or interpreted as being within 10%, 5%, 3%, 2%, 1% or 0.5% of a given value or range.

The ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

The electrical connection or coupling described in the present disclosure can refer to direct connection or indirect connection. In the case of direct connection, the end points of the two elements on the circuit are directly connected or connected to each other with a conductive line. In the case of indirect connection, there may be a switch, a diode, a capacitor, an inductor, another suitable element, or a combination thereof between the end points of the two elements on the circuit, but it is not limited thereto.

In the present disclosure, the thickness, length, width and area can be measured by using an optical microscope, and the thickness can be measured in a cross-sectional image by an electron microscope, but it is not limited thereto. In addition, any two values or directions used for comparison may have certain errors. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

Moreover, it should be understood that, in accordance with the embodiments of the present disclosure, an optical microscope (OM), a scanning electron microscope (SEM), a film thickness profiler (α-step), an ellipsometer or another suitable method may be used to measure the depth, thickness, width or height of each element, or spacing or distance between elements. Specifically, in accordance with some embodiments, a scanning electron microscope may be used to obtain a cross-sectional image including the elements to be measured, and the depth, thickness, width or height of each element, or spacing or distance between elements in the image can be measured.

In accordance with the embodiments of the present disclosure, the electronic device may include a display device, a tiled device, a touch electronic device, a sensing electronic device, a curved electronic device or a non-rectangular electronic device, but it is not limited thereto. The electronic device may include, for example, liquid crystal, light-emitting diode, fluorescence, phosphor, another suitable display medium, or a combination thereof, but it is not limited thereto. Electronic devices may include passive components and active components, such as capacitors, resistors, inductors, diodes, transistors, etc. The diode may include a light-emitting diode (LED) or a photodiode (photodiode). The light-emitting diode may include, for example, an organic light-emitting diode (OLED), a mini light-emitting diode (mini LED), a micro-light-emitting diode (micro LED) or a quantum dot light-emitting diode (quantum dot LED), but it is not limited thereto. The tiled device may be, for example, a tiled display device, but it is not limited thereto. It should be noted that the electronic device can be any combination of the above, but it is not limited thereto. In addition, the electronic device may be a bendable or flexible electronic device. In addition, the shape of the electronic device may be a rectangular shape, a circular shape, a polygonal shape, a shape with curved edges, or another suitable shape. The electronic device may have peripheral systems such as driving system, control system, light source system, shelf system, etc. to support the display device or tiled device. For convenience of explanation, the electronic device will be described below as a display device, but the present disclosure is not limited thereto.

When the electronic device is a display device, the display device may be a non-self-luminous display device or a self-luminous display device. The display device may include, for example, a diode, liquid crystal, a light-emitting diode (LED), quantum dot (QD), fluorescence, phosphor, or another suitable display medium or a combination thereof. The light-emitting diode may include, for example, an organic light-emitting diode (OLED), a mini light-emitting diode (mini LED), a micro light-emitting diode (micro LED) or a quantum dot light-emitting diode (QDLED), but it is not limited thereto.

The electronic device according to the embodiments of the present disclosure can be applied to, for example, digital galleries, mobile phones, tablet computers, public information displays, and/or other electronic devices that can be used outdoors or in environments with high-intensity ambient light. The electronic device may include a liquid-crystal display panel, an organic light-emitting diode display panel, a micro light-emitting diode display panel, a reflective display panel or another suitable display panel, but the present disclosure is not limited thereto.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, an electronic device is provided. The electronic device includes a specific design of light-shielding structure, which can reduce the lines showing color difference between the light-shielding structure and the active area of the protective substrate. The edges between the light-shielding structure and the active area can be blurred and softened, thereby improving the display quality.

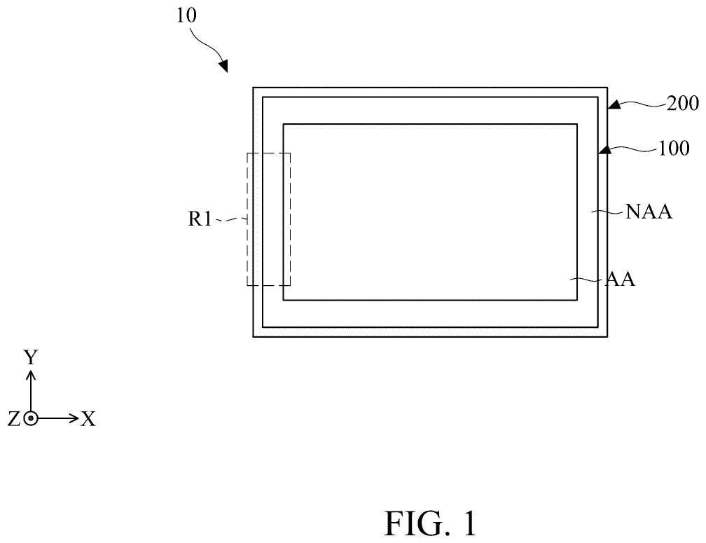

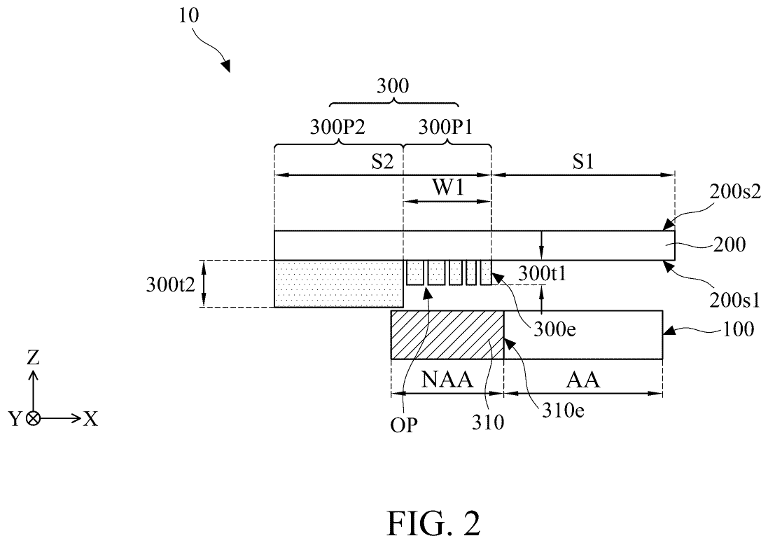

Please refer to FIG. 1 and FIG. 2. FIG. 1 is a top-view diagram of an electronic device 10 in accordance with some embodiments of the present disclosure. FIG. 2 is a cross-sectional diagram of the electronic device 10 corresponding to region R1 of FIG. 1 in accordance with some embodiments of the present disclosure. It should be understood that, for clarity of explanation, some components of the electronic device 10 may be omitted in the drawings, and only some components are schematically illustrated. In accordance with some embodiments, additional features may be added to the electronic device 10 described below.

As shown in FIG. 1 and FIG. 2, the electronic device 10 may include a panel 100, a protective substrate 200, and a first light-shielding structure 300. The panel 100 may have an active area AA and a peripheral area NAA adjacent to the active area AA. In accordance with some embodiments, the peripheral area NAA may be adjacent to at least one side of the active area AA. In accordance with some embodiments, the peripheral area NAA may be disposed surrounding the active area AA. In accordance with some embodiments, the active area AA may include, for example, a display area, a detecting area, a touch area, another suitable application area, or a combination thereof, and the peripheral area NAA may be an area other than the active area AA. The peripheral area NAA may, for example, include a peripheral wiring area, which includes outer lead bonding (OLB) for bonding electronic components (not illustrated), such as chips, flexible circuit boards, or other components.

In accordance with some embodiments, the panel 100 may include a display panel, a touch panel, a sensing or detecting device, or a combination thereof. In accordance with some embodiments, the panel 100 may include a curved panel, a rollable panel, a foldable panel, a stretchable panel or a non-rectangular panel, but it is not limited thereto. The panel 100 may include a non-self-luminous panel, a self-luminous panel, a reflective panel, a transflective panel or a transparent panel, but it is not limited thereto.

The protective substrate 200 may be disposed opposite to the panel 100. The protective substrate 200 may have a surface 200s1 and a surface 200s2. The surface 200s1 is closer to the panel 100, and the surface 200s2 is farther away from the panel 100. The surface 200s2 may be adjacent to the user's viewing surface. Furthermore, the protective substrate 200 can be used to protect structures such as the first light-shielding structure 300 and/or the panel 100 located below it. In accordance with some embodiments, the protective substrate 200 may optionally provide a surface for touch, operation, or another function, but it is not limited thereto. In accordance with some embodiments, other components, such as touch components or detecting components, may be optionally inserted between the protective substrate 200 and the panel 100, but it is not limited thereto. In accordance with some embodiments, a functional layer (not illustrated) may be optionally disposed on the protective substrate 200. For example, the functional layer may include an anti-reflective layer, an anti-glare layer, an anti-fouling layer, an anti-scratch layer, an anti-UV layer, another suitable functional layer or a combination thereof.

In accordance with some embodiments, the protective substrate 200 may include a flexible substrate, a rigid substrate, or a combination thereof, but it is not limited thereto. In accordance with some embodiments, the material of the protective substrate 200 may include glass, quartz, sapphire, ceramic, polyimide (PI), polycarbonate (PC), polyethylene terephthalate (PET), polypropylene (PP), another suitable material or a combination thereof, but it is not limited thereto. In accordance with some embodiments, the top-view profile of the protective substrate 200 and/or the panel 100 includes any shape, such as a rectangle, a circle, a polygon, or an irregular shape. The surface 200s1 or the surface 200s2 of the protective substrate 200 is not limited to a flat surface, and may optionally include a curved surface, a wavy surface or another special shape. The surface 200s1 and the surface 200s2 of the protective substrate 200 are not limited to extending in parallel. One of the surface 200s1 and the surface 200s2 may include a curved surface and the other may include a flat surface, but it is not limited thereto. The surface 200s1 and the surface 200s2 of the protective substrate 200 may have different degrees of curvature.

In accordance with some embodiments, the protective substrate 200 may include a first area S1 and a second area S2 adjacent to the first area S1. The first area S1 may overlap the active area AA, and the first area S1 may optionally partially overlap or not overlap the peripheral area NAA. In accordance with some embodiments, the second area S2 may overlap the peripheral area NAA.

In accordance with some embodiments, the first light-shielding structure 300 may be disposed on the surface 200s1 of the protective substrate 200 and correspond to the second area S2. The boundary between the first area S1 and the second area S2 may be defined, for example, by an inner edge 300e of the first light-shielding structure 300 adjacent to the active area AA. In accordance with some embodiments, the first light-shielding structure 300 may be disposed on the surface 200s1 of the protective substrate 200 and correspond to the peripheral area NAA of the panel 100. In accordance with some other embodiments (not illustrated), the first light-shielding structure 300 may be optionally disposed on the surface 200s2. In accordance with some embodiments, “the first light-shielding structure 300 corresponds to the peripheral area NAA of the panel 100” means that the first light-shielding structure 300 overlaps the peripheral area NAA in a top-view perspective of the electronic device 10. When referring to component A overlaps component B in a top-view perspective of the electronic device 10, it means that component A at least partially overlaps component B. In accordance with some other embodiments (not illustrated), the first light-shielding structure 300 may optionally partially overlap the active area AA. As shown in FIG. 2, the portion of the first light-shielding structure 300 overlapping the peripheral area NAA may have at least one opening OP. In accordance with some embodiments, the first light-shielding structure 300 may include a first portion 300P1 and a second portion 300P2 adjacent or connected to the first portion 300P1, and the first portion 300P1 is closer to the active area AA than the second portion 300P2. The first portion 300P1 has at least one opening OP. The opening OP may not penetrate or may penetrate the first portion 300P1. The opening OP may not penetrate the first portion 300P1. For example, in the normal direction (the Z direction) of the protective substrate 200, the depth (e.g., the maximum depth) of the opening OP may be smaller than the thickness of the first portion 300P1. The opening OP may penetrates the first portion 300P1. For example, in the normal direction (the Z direction) of the protective substrate 200, the depth (e.g., the maximum depth) of the opening OP is equal to the thickness of the first portion 300P1. In accordance with some embodiments, a part of the plurality of openings OP may not penetrate the first portion 300P1, and another part of the plurality of openings OP may penetrate the first portion 300P1. It should be noted that since the first portion 300P1 closer to the active area AA has the openings OP, the transmittance of the first light-shielding structure 300 can be gradually reduced from the active area AA to the peripheral area NAA, which can reduce the lines showing color difference between the first light-shielding structure 300 and the active area AA.

Furthermore, the first portion 300P1 has a thickness of 300t1, the second portion 300P2 has a thickness of 300t2, and the thickness 300t1 of the first portion 300P1 may be smaller than the thickness 300t2 of the second portion 300P2. In accordance with some embodiments, the thickness 300t1 of the first portion 300P1 may be between 100 micrometers (μm) and 8000 μm (i.e. 100 μm≤thickness 300t1≤8000 μm). In accordance with some embodiments, the thickness 300t2 of the second portion 300P2 may be between 200 μm and 16000 μm (i.e. 200 μm≤thickness 300t2≤16000 μm). In accordance with some embodiments, the thickness 300t1 is obtained by averaging the thicknesses measured at any three positions of the first portion 300P1 in the normal direction of the protective substrate 200 (for example, the Z direction in the drawing) in a cross-section. Similarly, in a cross section, the thickness 300t2 is obtained by averaging the thicknesses measured at any three positions of the second portion 300P2 in the normal direction of the protective substrate 200 (for example, the Z direction in the drawing) in a cross-section. In accordance with some embodiments, the first portion 300P1 and/or the second portion 300P2 may have a gradually changed thickness.

In accordance with some embodiments, the width W1 of the first portion 300P1 may be at least greater than or equal to 1 millimeter (mm), for example, may be greater than 1.5 mm, 2 mm, 2.5 mm, 3 mm, 3.5 mm, 4 mm, 4.5 mm, 5 mm, but it is not limited thereto. When the width W1 of the first portion 300P1 is at least greater than 1 mm or the above-mentioned suitable values, the first light-shielding structure 300 can have enough space to produce a progressive change in transmittance, thereby achieving an edge blurring effect. In accordance with some embodiments, the aforementioned width W1 refers to the maximum width of the first portion 300P1 in a direction perpendicular to the normal direction of the protective substrate 200 (for example, the X direction in the drawing). It should be noted that FIG. 2 is a cross-sectional view of area R1 in FIG. 1, and the first light-shielding structure 300 corresponding to the peripheral area NAA on other sides of the active area AA may also have a similar design.

In accordance with some embodiments, the material of the first light-shielding structure 300 may include photoresist (such as black photoresist or another suitable color photoresist), printing ink (such as black ink or another suitable color ink), resin (such as black resin or another suitable color resin), ferrous metal, another suitable light-shielding material, or a combination thereof, but it is not limited thereto.

In accordance with some embodiments, the first light-shielding structure 300 may be formed by a printing process such as a screen printing process or an inkjet printing process, a coating process, a deposition process, an evaporation process, a sputtering process, another suitable process, or a combination thereof. Then, the first light-shielding structure 300 may be patterned through a laser process to form the openings OP in the first portion 300P1, but it is not limited thereto. Furthermore, by adjusting the parameters of the laser process, openings OP having a specific shape, dimension (aperture, width, length or depth) or spacing between openings OP can be formed in the first portion 300P1.

In accordance with some embodiments, the electronic device 10 may include a second light-shielding structure 310. The second light-shielding structure 310 may be disposed in the peripheral area NAA of the panel 100. In a top-view direction (e.g., the Z direction) of the electronic device 10, a portion of the second light-shielding structure 310 may overlap the first light-shielding structure 300. In accordance with some embodiments, a portion of the second light-shielding structure 310 may overlap the first portion 300P1 of the first light-shielding structure 300 in a top-view direction (e.g., the Z direction) of the electronic device 10. In accordance with some embodiments, in a top-view direction of the electronic device 10, a portion of the second light-shielding structure 310 may overlap the first portion 300P1 and at least a portion of the second portion 300P2 of the first light-shielding structure 300. In accordance with some embodiments, in a top-view direction of the electronic device 10, at least one opening OP of the first light-shielding structure 300 overlaps the second light-shielding structure 310. In accordance with some embodiments, the projection of at least one opening OP of the first light-shielding structure 300 onto the surface 200s1 of the protective substrate 200 may be located within the projection of the second light-shielding structure 310 onto the surface 200s1 of the protective substrate 200. In accordance with some embodiments, the second light-shielding structure 310 may be a light-shielding structure in the panel 100. The second light-shielding structure 310 may be, for example, disposed on one of the substrates (not illustrated) in the panel 100. In accordance with some embodiments (not illustrated), the second light-shielding structure 310 may be optionally made of the same material layer as the black photoresist layer disposed in the active area AA of the panel 100, or the second light-shielding structure 310 may be optionally the same layer as the black photoresist layer disposed in the active area AA of the panel 100, but it is not limited thereto. In accordance with some embodiments (not illustrated), the second light-shielding structure 310 may be optionally made of a different material layer from the black photoresist layer disposed in the active area AA of the panel 100, or the second light-shielding structure 310 may be optionally a different layer from the black photoresist layer disposed in the active area AA of the panel 100. In accordance with some embodiments, in a top-view direction of the electronic device 10, the profile of the inner edge 310e of the second light-shielding structure 310 may substantially correspond to the profile of the inner edge 300e of the first light-shielding structure 300 (e.g., have the same shape) or may not correspond to the profile of the inner edge 300e of the first light-shielding structure 300 (with different shapes). In accordance with some embodiments, “the inner edge 310e of the second light-shielding structure 310 and the inner edge 300e of the first light-shielding structure 300 have substantially corresponding profiles” means that the inner edge 310e of the second light-shielding structure 310 and the inner edge 300e of the first light-shielding structure 300 are approximately equidistant at different positions (such as peripheral areas NAA corresponding to different sides of the active area AA), but it is not limited thereto. In accordance with some embodiments, “the inner edge 310e of the second light-shielding structure 310 and the inner edge 300e of the first light-shielding structure 300 have non-corresponding profiles” means that the distances between the inner edge 310e of the second light-shielding structure 310 and the inner edge of the first light-shielding structure 300e may be different at different locations (e.g., peripheral areas NAA corresponding to different sides of the active area AA). In accordance with some embodiments, the inner edge 300e of the first light-shielding structure 300 and the inner edge 310e of the second light-shielding structure 310 may be misaligned or aligned. In accordance with some embodiments, “in a top-view direction of the electronic device 10, the inner edge 300e of the first light-shielding structure 300 overlap the inner edge 310e of the second light-shielding structure 310” means that the inner edge 300e of the first light-shielding structure 300 and the inner edge 310e of the second light-shielding structure 310 are aligned. On the contrary, “in a top-view direction of the electronic device 10, the inner edge 300e of the first light-shielding structure 300 and the inner edge 310e of the second light-shielding structure 310 do not overlap” means that the inner edge 300e of the first light-shielding structure 300 and the inner edge 310e of the second light-shielding structure 310 are misaligned.

In accordance with some embodiments, the material of the second light-shielding structure 310 may include photoresist (such as black photoresist or another suitable color photoresist), printing ink (such as black ink or another suitable color ink), resin (such as black resin or another suitable color resin), ferrous metal, another suitable light-shielding material, or a combination thereof, but it is not limited thereto.

In accordance with some embodiments, the second light-shielding structure 310 may be formed by a printing process such as a screen printing process or an inkjet printing process, a coating process, a deposition process, an evaporation process, a sputtering process, another suitable process, or a combination thereof.

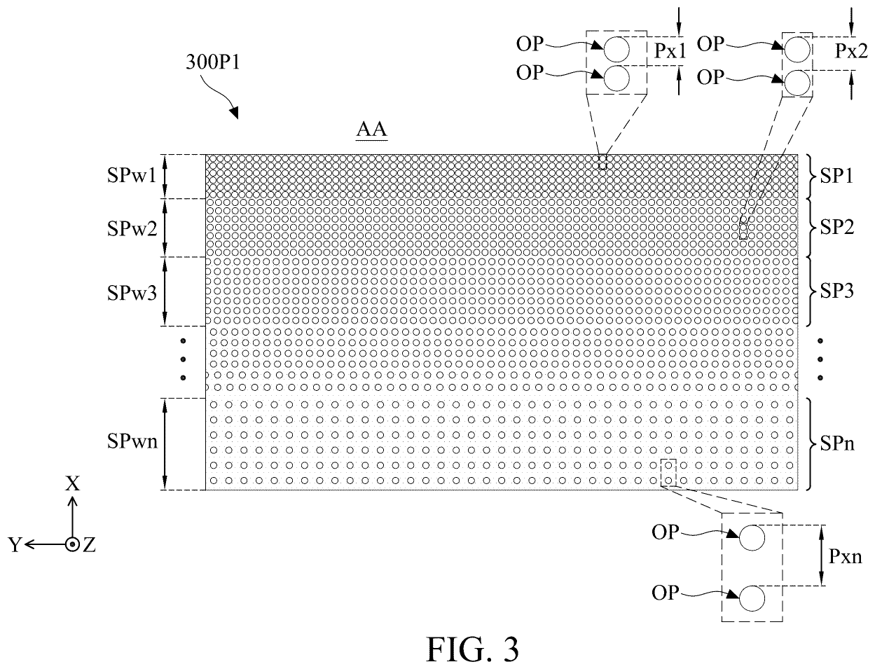

Next, please refer to FIG. 3, which is a partial top-view diagram of the first light-shielding structure 300 of the electronic device 10 in accordance with some embodiments of the present disclosure. Specifically, FIG. 3 illustrates a top-view diagram of the first portion 300P1 of the first light-shielding structure 300.

As shown in FIG. 3, in accordance with some embodiments, the first portion 300P1 of the first light-shielding structure 300 may have a plurality of openings OP, and the first portion 300P1 includes n sub-portions arranged in sequence (for example, the first sub-portion SP1, the second sub-portion SP2, the third sub-portion SP3 . . . the n-th sub-portions SPn), n is a positive integer greater than or equal to 2. The first sub-portion SP1 among the n sub-portions is, for example, closest to the active area AA, and the second sub-portion SP2 among the n sub-portions is adjacent to the side of the first sub-portion SP1 farther away from the active area AA, the third sub-portion SP3 among the n sub-portions is adjacent to the side of the second sub-portion SP2 farther away from the first sub-portion SP1, and so on. In other words, the second sub-portion SP2 may be located between the first sub-portion SP1 and the third sub-portion SP3, and so on. The spacing between two adjacent openings OP in the first sub-portion SP1 among the n sub-portions is a first pitch Px1. The spacing between the two adjacent openings OP in the second sub-portion SP2 among the n sub-portions is a second pitch Px2. The first pitch Px1 is, for example, smaller than the second pitch Px2, but it is not limited thereto. By analogy, the spacing between two adjacent openings OP in the n-1th sub-portion SPn-1 among the n sub-portions is the n-1th pitch Pxn-1, and the spacing between two adjacent openings OP in the n-th sub-portion SPn among the n sub-portions is the n-th pitch Pxn. Moreover, the n-th pitch Pxn is smaller than the n-1th pitch Pxn-1 and/or the second pitch Px2. In this embodiment, the dimensions (length, width, or depth) of the plurality of openings OP may be substantially the same. The substantially same dimensions may have an error range of, for example, 8%, but it is not limited thereto. In other embodiments, the dimensions (length, width or depth) of part of the plurality of openings OP may be different.

In this configuration, the pitch of the opening OP relatively close to the active area AA of the panel 100 (e.g., the first pitch Px1) is smaller than the pitch of the opening OP relatively far away from the active area AA (e.g., the second pitch Px2, and/or the n-th pitch Pxn). Therefore, the density of the openings OP of the first light-shielding structure 300 relatively close to the active area AA of the panel 100 is relatively large (or the total area of the openings OP is relatively large), so the transmittance is relatively large, while the density of the openings OP of the first light-shielding structure 300 relatively far away from the active area AA is relatively small (or the total area of the openings OP is relatively small), so the transmittance is relatively small. The transmittance of the first light-shielding structure 300 can be gradually reduced from the active area AA to the peripheral area NAA (for example, the difference in transmittance of the openings OP in adjacent sub-portions can be between 10% and 20%), thereby achieving color gradient effect. It should be noted that the above-mentioned transmittance can be gradually reduced from the active area AA to the peripheral area NAA, and the reduction is not limited to proportional reduction, and may also include non-proportional reduction.

In accordance with some embodiments, the aforementioned pitch refers to the distance between the same sides of two adjacent openings OP. Alternatively, the aforementioned pitch can also refer to the distance between the centers of two adjacent openings OP, and the center of the opening OP can be the geometric center. For example, if the opening OP is circular, the center of the opening OP may be the center of the circle; if the opening OP has a rectangular-like shape or square shape, the center may be the intersection of two diagonals; if the opening OP is irregularly shaped and the center cannot be defined in the above manners, a minimum circle that can surround the opening OP can be obtained, and the center of the minimum circle can be defined as the center of the opening OP.

As described above, although the openings OP shown in the drawings are all circular, they are not limited to this. In accordance with some embodiments, in the top-view diagram, the opening OP of the first light-shielding structure 300 may have a circular, rectangular or triangular shape, but it is not limited thereto. In accordance with different embodiments, the opening OP may have any other suitable shape, such as an ellipse, another polygon, an irregular shape, etc. In accordance with some embodiments, the plurality of openings OP of the first light-shielding structure 300 may all have the same shape. In accordance with some other embodiments, the first light-shielding structure 300 may have openings OP with different shapes.

In accordance with some embodiments, the difference between the second pitch Px2 and the first pitch Px1 may be at least less than or equal to 20 μm, 19 μm, 18 μm, 17 μm, 16 μm, 15 μm, 14 μm, 13 μm, 12 μm, 11 μm or 10 μm. In accordance with some embodiments, in the arrangement direction of the first portion 300P1 and the second portion 300P2 (for example, the X direction in the drawing), the widths of at least two of the n sub-portions are different. For example, the width SPw1 of the first sub-portion SP1 may be different from the width SPw2 of the second sub-portion SP2, the width SPw2 of the second sub-portion SP2 may be different from the width SPw3 of the third sub-portion SP3, and so on. In accordance with some embodiments, the width SPw1 of the first sub-portion SP1 may be less than the width SPw2 of the second sub-portion SP2, the width SPw2 of the second sub-portion SP2 may be less than the width SPw3 of the third sub-portion SP3, and so on. In accordance with some embodiments, the width SPw1 of the first sub-portion SP1, the width SPw2 of the second sub-portion SP2, the width SPw3 of the third sub-portion SP3 to the width SPwn of the n-th sub-portion SPn may gradually increase, but it is not limited thereto. It should be noted that the widths of the above-mentioned sub-portions may gradually increase, and the increase is not limited to proportional increase, and may also include non-proportional increase.

Based on the foregoing, in accordance with some embodiments, the transmittance of the first sub-portion SP1 may be greater than the transmittance of the second sub-portion SP2 among the n sub-portions, and the difference between the transmittance of the first sub-portion SP1 and the transmittance of the second sub-portion SP2 may be less than or equal to 10%, 9%, 8%, 7%, 6% or 5%. In accordance with some embodiments, the transmittance of the second sub-portion SP2 may be greater than the transmittance of the third sub-portion SP3, and the difference between the transmittance of the second sub-portion SP2 and the transmittance of the third sub-portion SP3 may be less than or equal to 10%, 9%, 8%, 7%, 6% or 5%. Similarly, the transmittance of the openings OP of the first light-shielding structure 300 relatively close to the active area AA of the panel 100 is high, and the transmittance of the openings OP of the first light-shielding structure 300 relatively far away from the active area AA is low. The transmittance of the light-shielding structure 300 can be gradually reduced from the active area AA to the peripheral area NAA, thereby achieving a color gradient effect.

It should be noted that FIG. 3 only illustrates a partial cross-sectional view, and the first light-shielding structure 300 corresponding to the peripheral area NAA on other sides of the active area AA may also have a similar design.

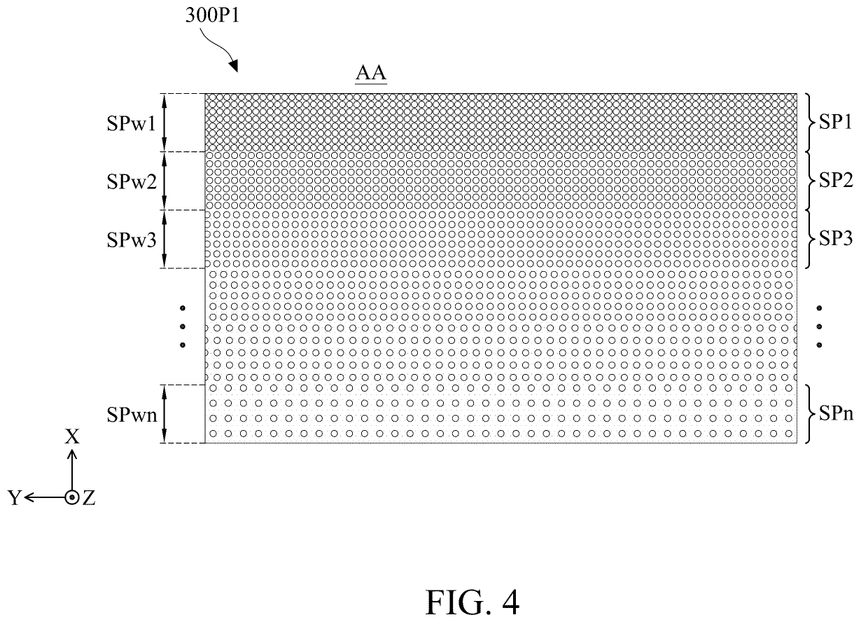

Next, please refer to FIG. 4, which is a partial top-view diagram of the first light-shielding structure 300 of the electronic device 10 in accordance with some other embodiments of the present disclosure. Specifically, FIG. 4 illustrates a top-view diagram of the first portion 300P1 of the first light-shielding structure 300.

As shown in FIG. 4, in accordance with some embodiments, in the arrangement direction of the first portion 300P1 and the second portion 300P2 (for example, the X direction in the drawing), the widths of the n sub-portions may be substantially the same. For example, the width SPw1 of the first sub-portion SP1 may be substantially the same as the width SPw2 of the second sub-portion SP2, the width SPw2 of the second sub-portion SP2 may be substantially the same as the width SPw3 of the third sub-portion SP3, and the width SPw3 of the third sub-portion SP3 also may be substantially the same as the width SPwn of the n-th sub-portion SPn. In accordance with some other embodiments, the widths of a part of the sub-portions are the same and the widths of another part of the sub-portions are different.

It should be noted that FIG. 4 only illustrates a partial cross-sectional view, and the first light-shielding structure 300 corresponding to the peripheral area NAA on other sides of the active area AA may also have a similar design.

It should be understood that although the interface between the n sub-portions of the first portion 300P1 in the drawing generally presents a straight line, it is not limited thereto. In accordance with some embodiments (not illustrated), the interface between the n sub-portions of the first portion 300P1 may be wavy, bent, irregular or another suitable shape, but it is not limited thereto.

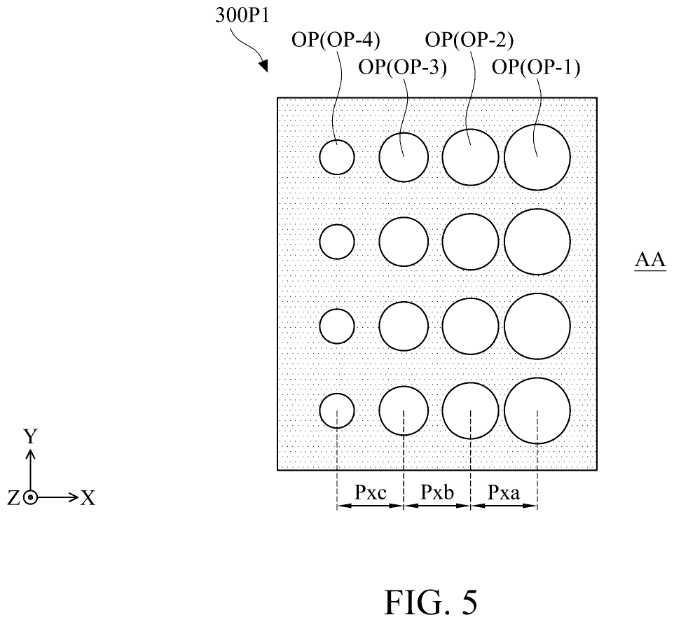

Next, please refer to FIG. 5, which is a partial top-view diagram of the first light-shielding structure 300 of the electronic device 10 in accordance with some other embodiments of the present disclosure. Specifically, FIG. 5 illustrates a top-view diagram of the first portion 300P1 of the first light-shielding structure 300.

As shown in FIG. 5, in accordance with some embodiments, the openings OP of the first portion 300P1 of the first light-shielding structure 300 may have different dimensions. In accordance with some embodiments, in a top-view direction (e.g., the Z direction) of the electronic device 10, the dimension of the opening OP (labeled as OP-1) closer to the active area AA among the plurality of openings OP is larger than the dimension of the opening OP (labeled as OP-2) farther away from the active area AA among the plurality of openings OP. In other words, the dimension of the opening OP (labeled as OP-1) relatively close to the active area AA is larger than the dimension of the opening OP (labeled as OP-2) relatively far away from the active area AA. The dimension of the opening OP (labeled as OP-2) relatively close to the active area AA is larger than the dimension of the opening OP (labeled as OP-3) relatively far from the active area AA. The dimension of the opening OP (labeled as OP-3) relatively close to the active area AA is larger than the dimension of the opening OP (labeled as OP-4) relatively far away from the active area AA, and so on. In this embodiment, a pitch Pxa between the openings OP (for example, the opening OP-1 and the opening OP-2) relatively close to the active area AA is substantially equal to a pitch Pxb between the openings OP (for example, the opening OP-2 and the opening OP3) relatively far away from the active area AA, but it is not limited thereto. The pitch Pxb between the openings OP (for example, the opening OP-2 and the opening OP-3) relatively close to the active area AA is substantially equal to the pitch Pxc between the openings OP (for example, the opening OP-3 and the opening OP-4) relatively far away from the active area AA, but it is not limited thereto.

In this configuration, the opening OP of the first light-shielding structure 300 relatively close to the active area AA of the panel 100 has a larger area (higher transmittance), while the opening OP of the first light-shielding structure 300 relatively far away from the active area AA has a smaller area (lower transmittance). The transmittance of the first light-shielding structure 300 can be gradually reduced from the active area AA to the peripheral area NAA, thereby achieving a color gradient effect.

It should be noted that FIG. 5 only illustrates a partial cross-sectional view, and the first light-shielding structure 300 corresponding to the peripheral area NAA on other sides of the active area AA may also have a similar design.

In accordance with some other embodiments (not illustrated), the design of the first light-shielding structure 300 can not only satisfy the requirement that the dimension of the opening OP relatively close to the active area AA is larger than the dimension of the opening OP relatively far away from the active area AA, but also can also comply with the requirements that the number of openings OP of the first light-shielding structure 300 relatively close to the active area AA of the panel 100 is larger or the density is higher (higher transmittance), while the number of openings OP of the first light-shielding structure 300 relatively far away from the active area AA is less or the density is lower (lower transmittance) at the same time, thereby achieving the effect of color gradient.

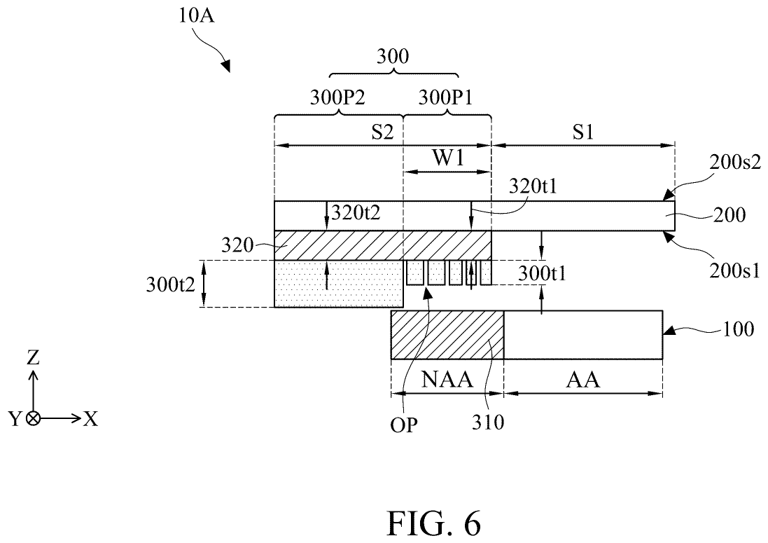

Next, please refer to FIG. 6, which is a partial cross-sectional diagram of an electronic device 10A in accordance with some other embodiments of the present disclosure. FIG. 6 shows a cross-sectional diagram of the electronic device 10A corresponding to region R1 of FIG. 1 in accordance with some other embodiments of the present disclosure. It should be understood that the same or similar components or elements in above and below contexts are represented by the same or similar reference numerals. The materials, manufacturing methods and functions of these components or elements are the same or similar to those described above, and thus will not be repeated in the following description.

The electronic device 10A in FIG. 6 is substantially similar to the aforementioned electronic device 10. The electronic device 10A may further include a third light-shielding structure 320. The third light-shielding structure 320 may be, for example, disposed between the first light-shielding structure 300 and the protective substrate 200, but it is not limited thereto. In accordance with some embodiments, the transmittance of a part of the third light-shielding structure 320 that is closer to the active area AA is higher than the transmittance of another part that is farther from the active area AA, but it is not limited thereto. In accordance with some embodiments, in the Z direction, the third light-shielding structure 320 may be optionally disposed between the first light-shielding structure 300 and the panel 100, or the third light-shielding structure 320 may be optionally disposed on the surface 200s2 of the protective substrate 200. In accordance with some embodiments, the third light-shielding structure 320 and the first light-shielding structure 300 may be in contact with each other, or there may be another transparent material layer (not illustrated) disposed between them.

In accordance with some embodiments (not illustrated), the thickness of the third light-shielding structure 320 can be adjusted so that the transmittance of the part adjacent to the active area AA is higher than that of another part far away from the active area AA. For example, the part of the third light-shielding structure 320 adjacent to the active area AA has a thickness 320t1, and the part of the third light-shielding structure 320 far away from the active area AA has a thickness 320t2. The thickness 320t1 may be, for example, smaller than the thickness 320t2, thereby making the part of the third light-shielding structure 320 adjacent to the active area AA has a relatively high transmittance, and achieving a gradual change in transmittance.

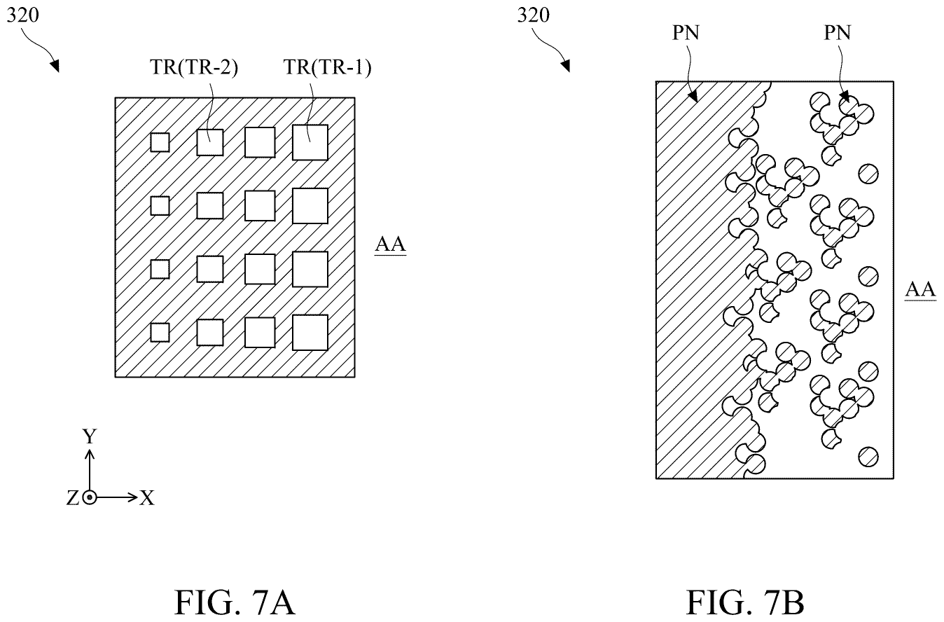

Alternatively, referring to FIG. 7A, in accordance with some other embodiments, the dimension of the light-transmitting region TR of the third light-shielding structure 320 can be adjusted, so that, for example, the part of the third light-shielding structure 320 closer to the active area AA has a relatively large light-transmitting area TR (labeled as TR1), and the part of the third light-shielding structure 320 farther away from the active area AA has a relatively small light-transmitting area TR (labeled as TR2). This allows the part of the third light-shielding structure 320 that is closer to the active area AA to have a relatively high transmittance, thereby achieving a gradual change in transmittance, but it is not limited thereto.

Alternatively, referring to FIG. 7B, in accordance with some other embodiments, the transmittance can be controlled by adjusting the distribution density of patterns PN of the third light-shielding structure 320. For example, the distribution density of the patterns PN of the third light-shielding structure 320 that is closer to the active area AA is smaller, and the distribution density of the patterns PN of the third light-shielding structure 320 that is farther away from the active area AA is larger, thereby making the part of the third light-shielding structure 320 closer to the active area AA has a relatively high transmittance and achieving a gradual change in transmittance, but it is not limited thereto.

In accordance with some embodiments, the third light-shielding structure 320, the first light-shielding structure 300 and/or the second light-shielding structure 310 may be made of different or similar materials. For examples of materials of the third light-shielding structure 320, please refer to the above descriptions of the first light-shielding structure 300. Similarly, the third light-shielding structure 320 may be formed by a printing process, such as a screen printing process or an inkjet printing process, a coating process, a deposition process, an evaporation process, a sputtering process, another suitable process, or a combination thereof. In accordance with some embodiments, the third light-shielding structure 320 and the first light-shielding structure 300 may be formed through the same or different processes, but it is not limited thereto.

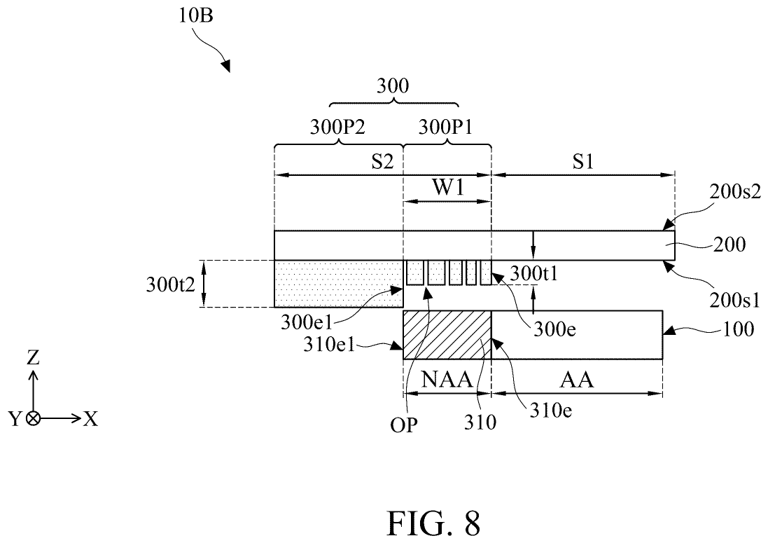

Next, please refer to FIG. 8, which is a partial cross-sectional diagram of an electronic device 10B in accordance with some other embodiments of the present disclosure. FIG. 8 shows a cross-sectional diagram of the electronic device 10B corresponding to region R1 of FIG. 1 in accordance with some other embodiments of the present disclosure.

The electronic device 10B in FIG. 8 is substantially similar to the aforementioned electronic device 10, but in the electronic device 10B, the inner edge 300e of the first portion 300P1 of the first light-shielding structure 300 is aligned with the inner edge 310e of the second light-shielding structure 310. In accordance with some embodiments, the inner edge 300e1 of the second portion 300P2 of the first light-shielding structure 300 may be aligned or misaligned with the outer edge 310e1 of the second light-shielding structure 310.

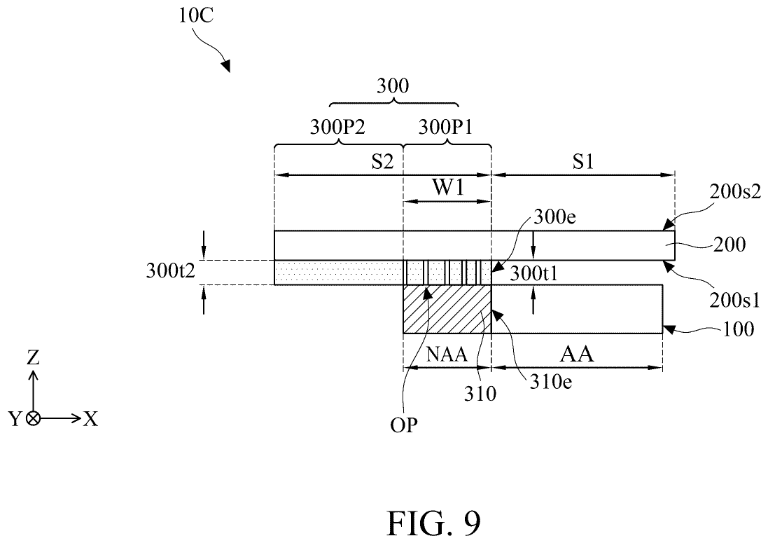

Next, please refer to FIG. 9, which is a partial cross-sectional diagram of an electronic device 10C in accordance with some other embodiments of the present disclosure. FIG. 9 shows a cross-sectional diagram of the electronic device 10C corresponding to region R1 of FIG. 1 in accordance with some other embodiments of the present disclosure.

The electronic device 10C in FIG. 9 is substantially similar to the aforementioned electronic device 10, but in the electronic device 10C, the thickness 300t1 of the first portion 300P1 of the first light-shielding structure 300 and the thickness 300t2 of the second portion 300P2 are substantially the same. In this embodiment, the density of the openings OP of the first light-shielding structure 300 relatively close to the active area AA of the panel 100 is higher (the transmittance is higher), and the density of the openings OP of the first light-shielding structure 300 relatively far away from the active area AA is lower (the transmittance is lower), and the transmittance of the first light-shielding structure 300 can be gradually reduced from the active area AA to the peripheral area NAA, thereby achieving a color gradient effect. In this embodiment, the inner edge 300e of the first portion 300P1 of the first light-shielding structure 300 may be aligned or misaligned with the inner edge 310e of the second light-shielding structure 310.

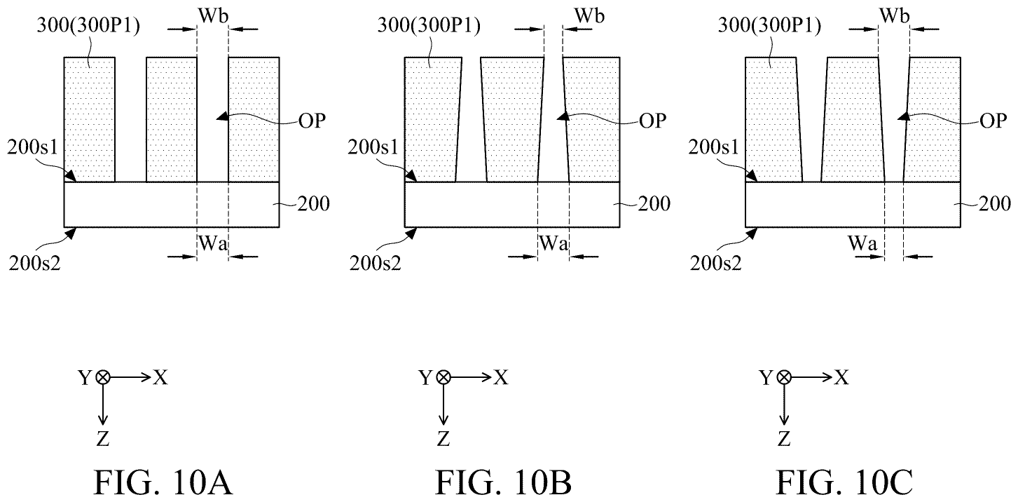

Next, please refer to FIGS. 10A to 10C, which are partial cross-sectional diagrams of some elements of an electronic device in accordance with some embodiments of the present disclosure. Specifically, FIGS. 10A to 10C illustrate partial cross-sectional diagrams of the protective substrate 200 and the first portion 300P1 of the first light-shielding structure 300 of the electronic device.

The first light-shielding structure 300 is disposed on the surface 200s1 of the protective substrate 200. As described above, the opening OP may be formed in the first portion 300P1 of the first light-shielding structure 300 through a laser process. The opening OP has, for example, a first width Wb and a second width Wa. The first width Wb may be the width of the opening OP away from the surface 200s1 of the protective substrate 200, and the second width Wa may be the width of the opening OP adjacent to the surface 200s1 of the protective substrate 200. As shown in FIG. 10A, in accordance with some embodiments, the first width Wb of the opening OP is substantially equal to the second width Wa, and the cross-sectional width (not labeled) substantially corresponding to the middle area of the opening OP may also be equal to the first width Wb or the second width Wa. As shown in FIG. 10B and FIG. 10C, in accordance with some embodiments, the first width Wb of the opening OP is different from the second width Wa. In accordance with some embodiments, as shown in FIG. 10B, the first width Wb of the opening OP is less than the second width Wa, and the cross-sectional width (not labeled) substantially corresponding to the middle area of the opening OP may be less than the second width Wa and greater than the first width Wb. In accordance with some embodiments, as shown in FIG. 10C, the first width Wb of the opening OP is greater than the second width Wa, and the cross-sectional width (not labeled) substantially corresponding to the middle area of the opening OP may be greater than the second width Wa and less than the first width Wb.

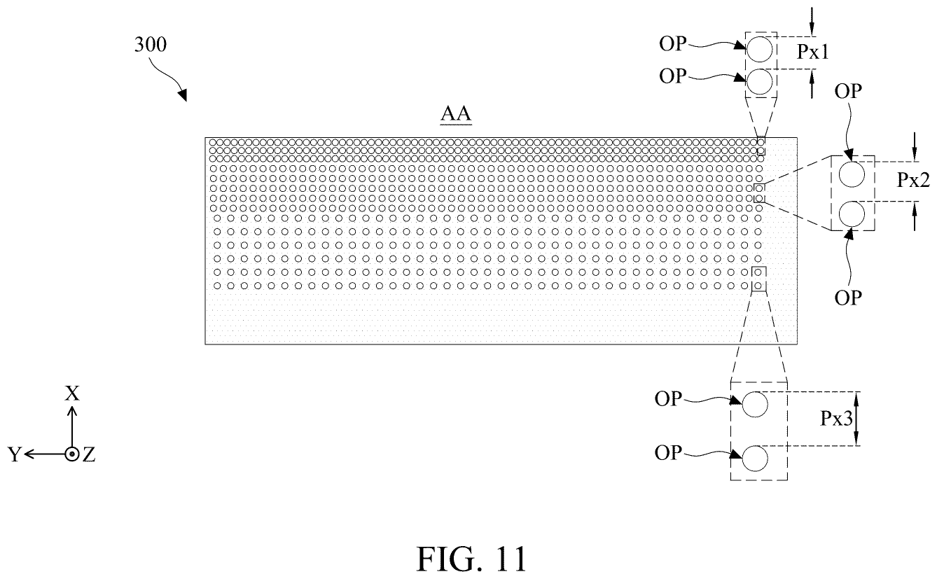

Next, please refer to FIG. 11, which is a partial top-view diagram of the first light-shielding structure 300 of the electronic device in accordance with some embodiments of the present disclosure.

As described above, the first light-shielding structure 300 (the first portion 300P1) may have a plurality of openings OP, and the pitch between two adjacent openings OP relatively adjacent to the active area AA (for example, the first pitch Px1) is smaller than the pitch between two adjacent openings OP relatively far away from the active area AA (for example, the second pitch Px2). Similarly, the pitch between two adjacent openings OP relatively adjacent to the active area AA (for example, the second pitch Px2) is smaller than the pitch between two adjacent openings OP relatively far away from the active area AA (for example, the third pitch Px3). In this embodiment, the change in pitch between the openings OP may be continuous and progressive. Specifically, in the X direction, the pitch between any two adjacent openings OP may be different. As the distance from the active area AA increases, the pitch between any two adjacent openings OP also gradually increases. In accordance with some embodiments, the difference between the second pitch Px2 and the first pitch Px1 (i.e. Px2−Px1) is the same as or different from the difference between the second pitch Px2 and the third pitch Px3 (i.e. Px3−Px2). In accordance with some embodiments, the ratio of the second pitch Px2 to the first pitch Px1 (i.e. Px2/Px1) is the same as or different from the ratio of the second pitch Px2 to the third pitch Px3 (i.e. Px3/Px2). In this embodiment, the dimensions of the plurality of openings OP are substantially the same.

In this configuration, the pitch of the openings OP relatively close to the active area AA (such as the first pitch Px1) is smaller than the pitch of the openings OP relatively far away from the active area AA (such as the second pitch Px2, or the third pitch Px3). Therefore, the density of openings OP of the first light-shielding structure 300 relatively close to the active area AA is relatively high (transmittance is higher), while the density of the openings OP of the first light-shielding structure 300 relatively far away from the active area AA is relatively low (transmittance is low). In addition, since the pitches between the openings OP are continuously and progressively reduced, the change in transmittance is also continuously and progressively reduced (for example, the difference in transmittance between adjacent openings OP can be between 1% to 10%, between 1% and 8%, between 1% and 7%, between 1% and 6%, or between 1% and 5%). Therefore, a softer color gradient effect can be achieved.

To summarize the above, according to the embodiments of the present disclosure, the electronic device provided includes a specific design of light-shielding structure, which can reduce the lines showing color difference between the light-shielding structure and the active area of the protective substrate. The edges between the light-shielding structure and the active area can be blurred and softened, which can improve the overall black effect in dark states and make the displayed images in bright states have a sense of extension, thus improving the performance of the electronic device.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a panel having an active area and a peripheral area adjacent to the active area;
a protective substrate disposed opposite to the panel; and
a first light-shielding structure disposed on a surface of the protective substrate and corresponds to the peripheral area, wherein a portion of the first light-shielding structure overlapping the peripheral area has at least one opening.

2. The electronic device as claimed in claim 1, wherein the first light-shielding structure comprises a first portion and a second portion adjacent to the first portion, a thickness of the first portion is less than a thickness of the second portion, the first portion is closer to the active area than the second portion, the first portion has the at least one opening, and a width of the first portion is at least greater than or equal to 1 millimeter.

3. The electronic device as claimed in claim 2, wherein the thickness of the first portion is between 100 micrometers and 8000 micrometers.

4. The electronic device as claimed in claim 2, wherein the thickness of the second portion is between 200 micrometers and 16000 micrometers.

5. The electronic device as claimed in claim 2, wherein the first portion of the first light-shielding structure has a plurality of openings, the first portion comprises n sub-portions arranged in sequence, n is a positive integer greater than or equal to 2, a first sub-portion among the n sub-portions is closest to the active area, a second sub-portion among the n sub-portions is adjacent to a side of the first sub-portion far away from the active area, a spacing between two adjacent openings in the first sub-portion is a first pitch, a spacing between two adjacent openings in the second sub-portion is a second pitch, and the first pitch is smaller than the second pitch.

6. The electronic device as claimed in claim 5, wherein a difference between the second pitch and the first pitch is less than or equal to 20 micrometers.

7. The electronic device as claimed in claim 5, wherein in an arrangement direction of the first portion and the second portion, the widths of at least two of the n sub-portions are different.

8. The electronic device as claimed in claim 2, wherein the first portion comprises n sub-portions arranged in sequence, n is a positive integer greater than or equal to 2, a first sub-portion among the n sub-portions is closest to the active area, a second sub-portion among the n sub-portions is adjacent to a side of the first sub-portion far away from the active area, and a transmittance of the first sub-portion is greater than a transmittance of the second sub-portion.

9. The electronic device as claimed in claim 8, wherein the difference between the transmittance of the first sub-portion and the transmittance of the second sub-portion is less than or equal to 10%.

10. The electronic device as claimed in claim 1, further comprising a second light-shielding structure disposed in the peripheral area of the panel, wherein in a top-view direction of the electronic device, a part of the second light-shielding structure overlaps the first light-shielding structure.

11. The electronic device as claimed in claim 10, wherein the at least one opening of the first light-shielding structure overlaps the second light-shielding structure.

12. The electronic device as claimed in claim 10, wherein a profile of an inner edge of the second light-shielding structure substantially corresponds to a profile of an inner edge of the first light-shielding structure.

13. The electronic device as claimed in claim 10, wherein a profile of an inner edge of the second light-shielding structure does not correspond to a profile of an inner edge of the first light-shielding structure.

14. The electronic device as claimed in claim 1, wherein the first light-shielding structure has a plurality of openings, and a dimension of the first opening among the plurality of openings closer to the active area is larger than a dimension of the second opening among the plurality of openings farther away from the active area.

15. The electronic device as claimed in claim 1, further comprising a third light-shielding structure disposed between the first light-shielding structure and the protective substrate, wherein a transmittance of a part of the third light-shielding structure closer to the active area is higher than a transmittance of another part of the third light-shielding structure farther away from the active area.

16. The electronic device as claimed in claim 15, wherein the part of the third light-shielding structure closer to the active area has a first thickness, the another part of the third light-shielding structure farther away from the active area has a second thickness, and the first thickness is smaller than the second thickness.

17. The electronic device as claimed in claim 15, wherein the part of the third light-shielding structure closer to the active area has a relatively large light-transmitting area, and the another part of the third light-shielding structure farther away from the active area has a relatively small light-transmitting area.

18. The electronic device as claimed in claim 1, wherein the first portion of the first light-shielding structure has a plurality of openings, a density of a part of the plurality of openings closer to the active area is higher than a density of another part of the plurality of openings farther away from the active area.

19. The electronic device as claimed in claim 2, wherein the first portion of the first light-shielding structure has a plurality of openings, and in a normal direction of the protective substrate, a depth of at least one of the plurality of openings is smaller than the thickness of the first portion. 20. The electronic device as claimed in claim 2, wherein the first portion of the first light-shielding structure has a plurality of openings, and in a normal direction of the protective substrate, a depth of at least one of the plurality of openings is equal to the thickness of the first portion.
